(19) United States
(12) Patent Application Publication
(10) Pub. No.: US 2013/0161808 A1
(43) Pub. Date: Jun. 27, 2013

(54) SEMICONDUCTOR PACKAGE AND METHOD OF MANUFACTURING SEMICONDUCTOR PACKAGE

(71) Applicant: SAMSUNG ELECTRO-MECHANICS CO., LTD., Suwon (KR)

(72) Inventors: Min Sung Kim, Suwon (KR); Sang Duck Kim, Suwon (KR)

(73) Assignee: SAMSUNG ELECTRO-MECHANICS CO., LTD., Suwon (KR)

(21) Appl. No.: 13/724,606

(22) Filed: Dec. 21, 2012

(30) Foreign Application Priority Data
Dec. 23, 2011 (KR) 10-2011-141402

(51) Int. Cl. H01L 23/00

(52) U.S. Cl. CPC H01L 24/09; H01L 24/81
USPC 257/686; 438/109

(57) ABSTRACT

Disclosed herein are a semiconductor package and a method of manufacturing the same. According to a preferred embodiment of the present invention, the semiconductor package includes: a first package having a first semiconductor element mounted on an upper portion thereof and at least one solder ball formed on a lower portion thereof; a second package stacked on the upper portion of the first package; and an interposer formed between the first package and the second package.

### CROSS REFERENCE TO RELATED APPLICATION

This application claims the benefit of Korean Patent Application No. 10-2011-0141402, filed on Dec. 23, 2011, entitled “Semiconductor Package and Method of Manufacturing Semiconductor Package”, which is hereby incorporated by reference in its entirety into this application.

### BACKGROUND OF THE INVENTION

1. Technical Field

The present invention relates to a semiconductor package and a method of manufacturing a semiconductor package.

2. Description of the Related Art

With the development of electronic industries, a demand for multi-functional and miniaturized electronic components has been suddenly increased. In order to cope with the demand, a single electronic element on the existing printed circuit board is being changed to a stack package substrate formed by overlappingly stacking several electronic elements on a single substrate.

An example of the stack package may include a package on package (POP) in which an upper layer package is stacked on a lower layer package. The POP includes an interposer formed between the lower layer package and the upper layer package in order to secure a space for electronic elements of the lower layer package between the lower layer package and the upper layer package and connect electrical signals from the upper layer package to the lower layer package. The interposer may be bonded to the lower layer package and the upper layer package, respectively, by a solder ball (Korean Patent Laid-Open Publication No. 2007-0118869). As such, as the interposer is bonded to the upper layer package and the lower layer package by the solder ball, a miss align may occur between the interposer and the upper layer package and the lower layer package. Further, as a solder ball pitch is reduced recently, the adhesion and solidity of the POP structure may be reduced due to the reduced bonding area of the solder ball and the interposer and the upper layer package and the lower layer package, respectively. Further, the lower layer package needs to be subjected to reflow in order to bond the solder ball for being bonded to the interposer and form a solder bump for being bonded to electronic elements. Therefore, a bump void and a damage of the POP may occur due to a large number of reflows.

### SUMMARY OF THE INVENTION

The present invention has been made in an effort to provide a semiconductor package capable of reducing the number of reflow processes and a method of manufacturing a semiconductor package.

Further, the present invention has been made in an effort to provide a semiconductor package capable of preventing a miss align between a package and an interposer and a method of manufacturing a semiconductor package.

In addition, the present invention has been made in an effort to provide a semiconductor package capable of being firmly stacked between a package and an interposer and a method of manufacturing a semiconductor package.

According to a preferred embodiment of the present invention, there is provided a semiconductor package, including: a first package having a first semiconductor element mounted on an upper portion thereof and at least one solder ball formed on a lower portion thereof; a second package stacked on the upper portion of the first package; and an interposer formed between the first package and the second package and formed so that a lower portion of the interposer adheres to the upper portion of the first package and an upper portion thereof adheres to a lower portion of the second package.

The interposer may electrically connect the first package and the second package.

The interposer may include: an interposer substrate made of an insulating material; a third bonding pad formed below the interposer substrate and bonded to the first package by a solder bump; a third solder resist formed below the interposer substrate and formed to expose the third bonding pad; a fourth bonding pad formed above the interposer substrate and bonded to the second package by the solder bump; a fourth solder resist formed above the interposer substrate and formed to expose the fourth bonding pad; and a through via formed to penetrate through the interposer substrate and electrically connecting the third bonding pad and the fourth bonding pad.

The first package may include: a first base substrate; a first bonding pad formed above the first base substrate and bonded to the interposer by the solder bump; and a first solder resist formed above the first base substrate and formed to expose the first bonding pad.

An upper portion of the first solder resist of the first package and a lower portion of a third solder resist of the interposer may be bonded to each other.

The first package may further include a device mounting pad formed above the first base substrate and mounted with the first semiconductor device.

The second package may include: a second base substrate; a second bonding pad formed below the second base substrate and bonded to the interposer by the solder bump; and a second solder resist formed above the second base substrate and formed to expose the second bonding pad.

A lower portion of a second solder resist of the second package and an upper portion of a fourth solder resist of the interposer may be bonded to each other.

The semiconductor package may further include: a semiconductor device mounted on the second base substrate.

According to another preferred embodiment of the present invention, there is provided a method of manufacturing a semiconductor package, including: preparing a first package; applying a first solder paste to an upper portion of the first package; stacking an interposer to the upper portion of the first package to which the first solder paste is applied; performing a first reflow; applying a second solder paste to the upper portion of the interposer; stacking the second package on the upper portion of the interposer to which the second solder paste is applied; and performing a second reflow.

In the applying of the first solder paste, a first solder paste may be formed above the first package and may be applied to an upper portion of a first bonding pad exposed to the outside by a first solder resist formed above the first package.

In the stacking of the interposer on the upper portion of the first package, an upper portion of the first solder resist formed above the first package and a lower portion of a third solder resist of a lower portion of the interposer may be bonded to each other.

In the performing of the first reflow, the first solder paste may be formed as a first solder bump by the first reflow.

In the applying of the second solder paste, a second solder paste may be formed above the interposer and may be applied to an upper portion of a fourth bonding pad exposed to the outside by a fourth solder resist formed above the interposer.

In the stacking of the second package on the upper portion of the interposer, an upper portion of a fourth solder resist formed above the interposer and a lower portion of a second solder resist formed below the second package may be bonded to each other.

In the performing of the second reflow, the second solder paste may be formed as a second solder bump by a second reflow.

In the applying of the first solder paste, the first solder paste may be formed above the first package and may be applied to an upper portion of a mounting pad on which a semiconductor device is mounted.

The method may further include: after the applying of the first solder paste, applying the semiconductor device on an upper portion of the mounting pad of the first package.

The method may further include: after the applying of the first solder paste, mounting a semiconductor device on an upper portion of the mounting pad of the first package.

### BRIEF DESCRIPTION OF THE DRAWINGS

The above and other objects, features and advantages of the present invention will be more clearly understood from the following detailed description taken in conjunction with the accompanying drawings, in which:

FIG. 1 is an exemplified diagram illustrating a semiconductor package according to a preferred embodiment of the present invention;

FIG. 2 is an exemplified diagram illustrating an upper structure of a first package according to a preferred embodiment of the present invention;

FIG. 3 is an exemplified diagram illustrating a lower structure of a second package according to a preferred embodiment of the present invention;

FIG. 4 is an exemplified diagram illustrating an interposer according to a preferred embodiment of the present invention; and

FIGS. 5 to 11 are diagrams illustrating a method for manufacturing a semiconductor package according to another preferred embodiment of the present invention.

### DESCRIPTION OF THE PREFERRED EMBODIMENTS

The above and other objects, features and advantages of the present invention will be more clearly understood from preferred embodiments and the following detailed description taken in conjunction with the accompanying drawings. In the specification, in adding reference numerals to components throughout the drawings, it is to be noted that like reference numerals designate like components even though components are shown in different drawings. Further, when it is determined that the detailed description of the known art related to the present invention may obscure the gist of the present invention, the detailed description thereof will be omitted. In the description, the terms “first”, “second”, and so on are used to distinguish one element from another element, and the elements are not defined by the above terms.

Hereinafter, preferred embodiments of the present invention will be described in detail with reference to the accompanying drawings.

Hereinafter, a semiconductor package and a method for manufacturing a semiconductor package according to preferred embodiments of the present invention will be described with reference to the accompanying drawings.

### Semiconductor Package

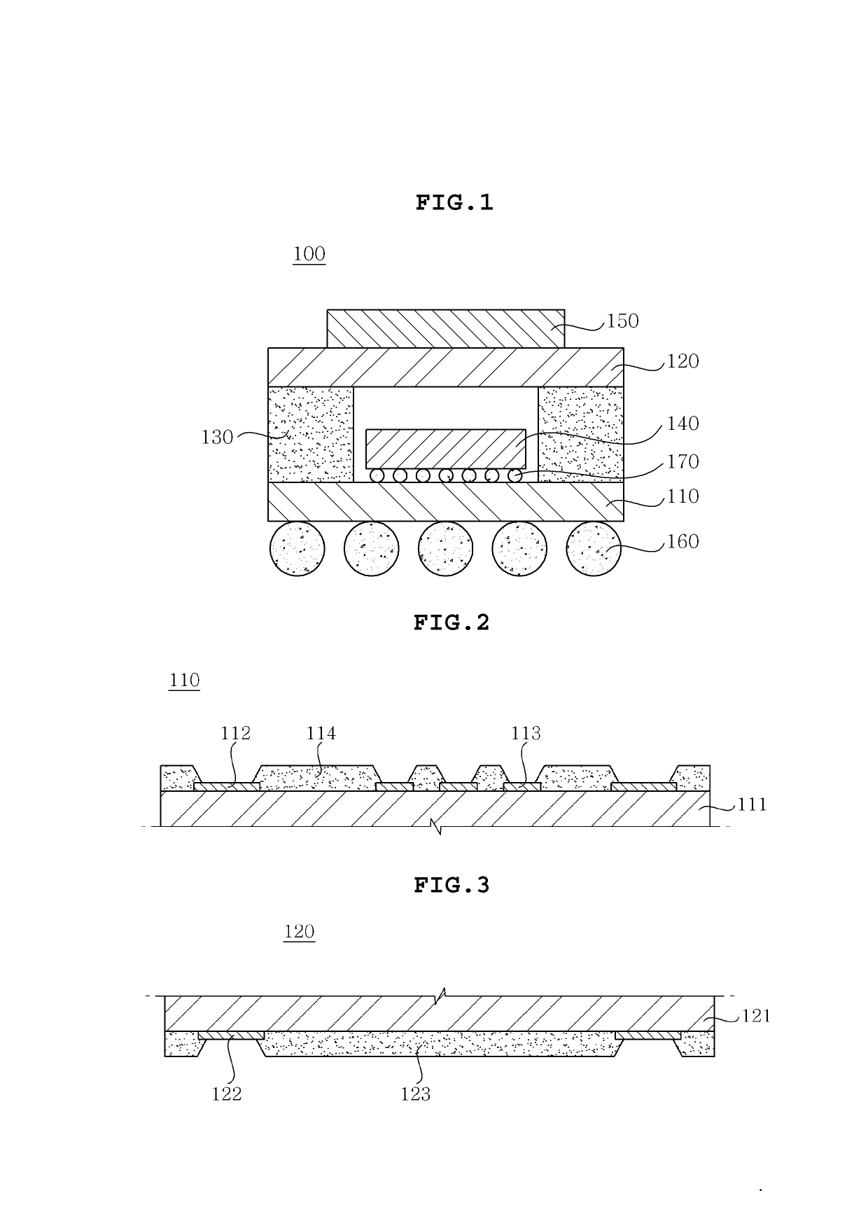

FIG. 1 is an exemplified diagram illustrating a semiconductor package according to a preferred embodiment of the present invention.

Referring to FIG. 1, a semiconductor package 100 may include a first package 110, a second package 120, and an interposer 130.

The first package 110 may be a lower layer package of the semiconductor package 100 having a stack structure. An upper portion of the first package 110 may be provided with a first semiconductor element 140. In this case, the first package 110 and the first semiconductor device 140 may be bonded to each other by a first solder bump 170. Further, the upper portion of the first package 110 may be provided with the interposer 130. A lower portion of the first package 110 may be provided with a plurality of solder balls 160. A ball grid array (BGA) may be configured by the plurality of solder balls formed as described above. For convenience of explanation, a detailed inner layer circuit configuration of the first package 110 is omitted in FIG. 1. However, it may be sufficiently recognized by those skilled in the art that the first package 110, which is a printed circuit board, may be provided with an inner layer circuit or an outer layer circuit of at least one layer.

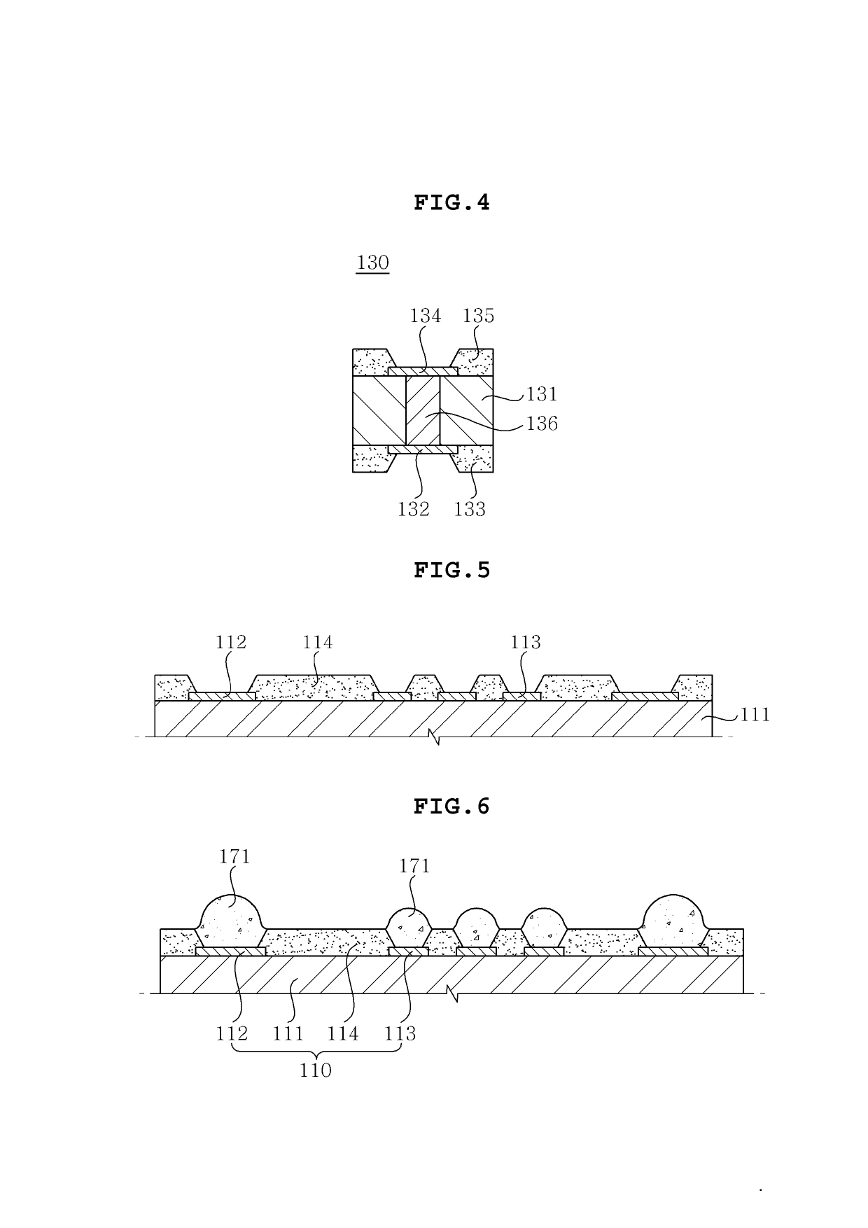

The second package 120 may be an upper layer package of the semiconductor package 100 having a stack structure. The second package 120 may be formed above the first package 110 so as to be spaced by a predetermined interval due to the interposer 130. An upper portion of the second package 120 may be provided with a second semiconductor element 150. Further, a lower portion of the second package 120 may be provided with the interposer 130. For convenience of explanation, a detailed inner layer circuit configuration of the second package 120 is omitted in FIG. 2. However, it may be sufficiently recognized by those skilled in the art that the second package 120, which is a printed circuit board, may be provided with an inner layer circuit or an outer layer circuit of at least one layer.

The interposer 130 may be formed to support the first package 110 and the second package 120 so as to be spaced by a predetermined space. To this end, the interposer 130 may be formed between the first package 110 and the second package 120. A lower portion of the interposer 130 may adhere to the upper portion of the first package 110. Further, an upper portion of the interposer 130 may adhere to the lower portion of the second package 120. The interposer 130 formed as described above may be electrically connected with the first package 110. Further, the interposer 130 may be electrically connected with the second package 120. That is, the first package 110 and the second package 120 may be electrically connected by the interposer 130.

The semiconductor package according to the preferred embodiment of the present invention may be formed to have a stable structure by removing the solder balls that have been used in the prior art, at the time of bonding the interposer to the first package and the second package. Further, according to the semiconductor package and the method of manufacturing a semiconductor package of the preferred embodiment of the present invention, it is possible to reduce a thickness of the semiconductor package by removing the solder balls according to the prior art and directly bonding and stacking the package and the interposer.

FIG. 2 is an exemplified diagram illustrating an upper structure of a first package according to a preferred embodiment of the present invention.

Referring to FIG. 2, the first package 110 may include a first base substrate 111, a first bonding pad 112, a device mounting pad 113, and a first solder resist 114.

Although not illustrated in FIG. 2, the first base substrate 111 may be provided with an inner layer circuit of at least one layer. The upper portion of the first base substrate 111 may be provided with a plurality of first bonding pads 112, a plurality of device mounting pads 113, and a first solder resist 114.

The first bonding pad 112 may be formed above the first base substrate 111. The first bonding pad 112 is a component that is bonded to the interposer (130 of FIG. 1) by a solder bump. The first bonding pad 112 may be electrically connected with the interposer (130 of FIG. 1). Therefore, the first bonding pad 112 may be made of an electrical conductive material. The interposer (130 of FIG. 1) is a component for supporting the first package 110 and the second package 120 and therefore, the first bonding pads 112 may be formed on both sides of the first package 110 on which the interposers (130 of FIG. 1) are mounted. The number of first bonding pads 112 may be determined corresponding to the number of interposers (130 of FIG. 1). Further, the location of the first bonding pad 112 may be determined corresponding to a location at which the interposer (130 of FIG. 1) is formed.

The device mounting pad 113 may be formed above the first base substrate 111. The device mounting pad 113 is a component that is bonded to the first semiconductor device (140 of FIG. 1) mounted on the first package 110, by the solder bump. The device mounting pad 113 may be electrically connected with the first semiconductor device (140 of FIG. 1). Therefore, the device mounting pad 113 may be made of an electrical conductive material. In order to stably mount the first semiconductor device (140 of FIG. 1), the device mounting pad 113 may be formed in plural.

The first solder resist 114 may be formed above the first base substrate 111. The first solder resist 114 is formed above the first base substrate 111, but may be formed so as to expose the first bonding pad 112 to the outside. Further, the first solder resist 114 is formed above the first base substrate 111, but may be formed so as to expose the device mounting pad 113 to the outside. The first solder resist 114 may be formed to protect the first package 110 from the external environment. For example, when the interposer (130 of FIG. 1) and the first semiconductor device (140 of FIG. 1) are bonded to the upper of the first package 110, it is possible to prevent the upper portion of the first package 110 from being damaged from the solder bump (170 of FIG. 1).

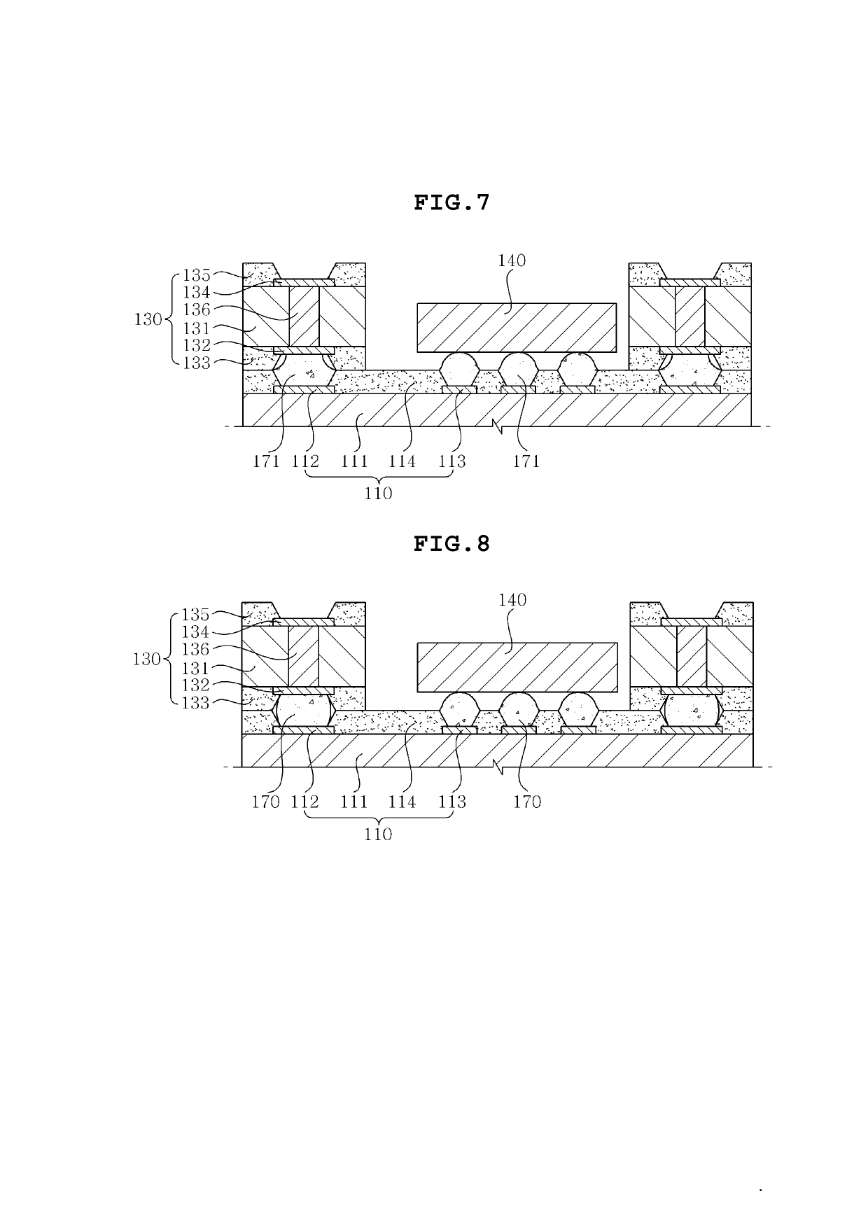

FIG. 3 is an exemplified diagram illustrating a lower structure of a second package according to a preferred embodiment of the present invention.

Referring to FIG. 3, the second package 120 may include a second base substrate 121, a second bonding pad 122, and a second solder resist 123.

Although not illustrated in FIG. 3, the second base substrate 121 may be provided with an inner layer circuit of at least one layer. A lower portion of the second base substrate 121 may be provided with a plurality of second bonding pads 122 and a second solder resist 123.

The second bonding pad 122 may be formed below the second base substrate 121. The first bonding pad 122 is a component that is bonded to the interposer (130 of FIG. 1) by a solder bump. The second bonding pad 122 may be electrically connected with the interposer (130 of FIG. 1). Therefore, the second bonding pad 122 may be made of an electrical conductive material. The number of second bonding pads 122 may be determined corresponding to the number of interposers (130 of FIG. 1). Further, the location of the second bonding pad 122 may be determined corresponding to a location at which the interposer (130 of FIG. 1) is formed.

The second solder resist 123 may be formed below the second base substrate 121. The second solder resist 123 is formed below the second base substrate 121, but may be formed so as to expose the second bonding pad 122 to the outside. The second solder resist 123 may be formed to protect the second package 120 from the external environment. For example, when the interposer (130 of FIG. 1) is bonded to the lower of the second package 120, it is possible to prevent the lower portion of the second package 120 from being damaged from the solder bump.

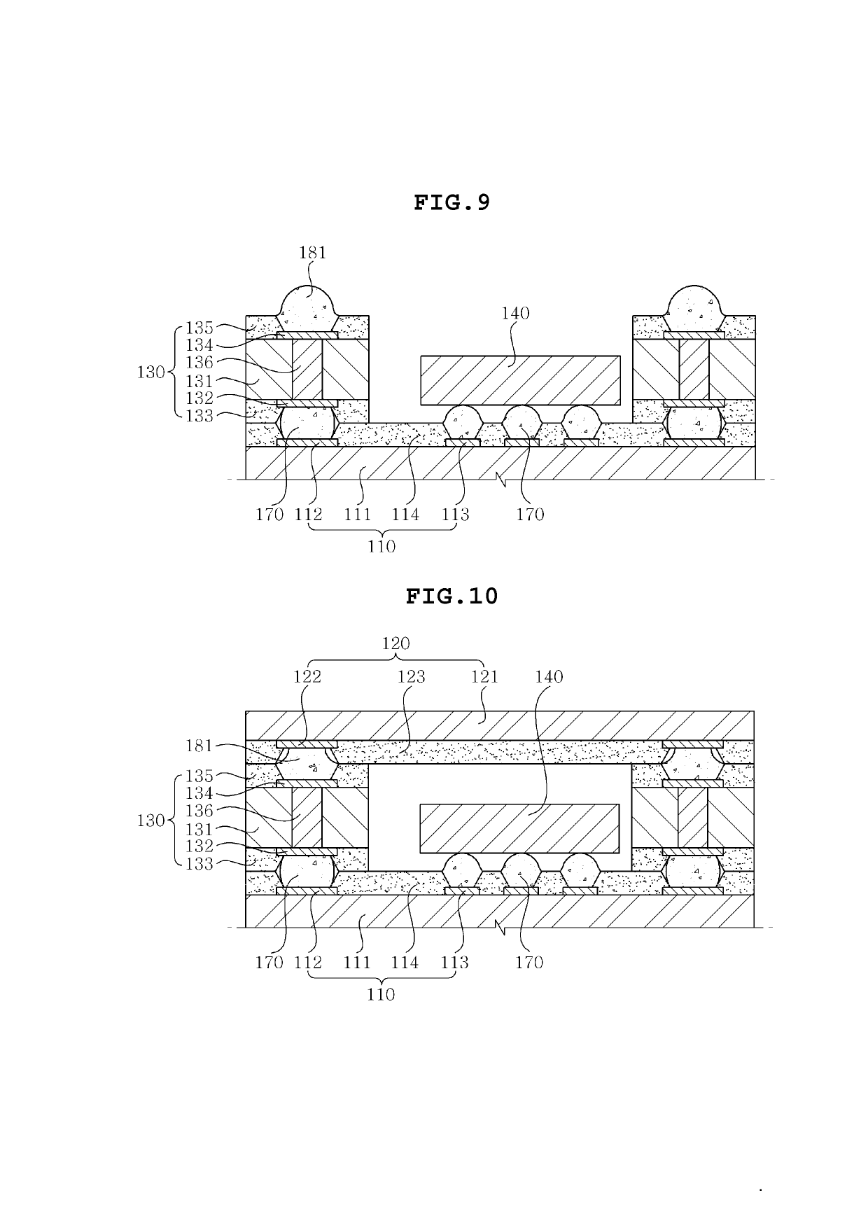

FIG. 4 is an exemplified diagram illustrating an interposer according to a preferred embodiment of the present invention.

Referring to FIG. 4, the interposer 130 may include an interposer substrate 131, a third bonding pad 132, a third solder resist 133, a fourth bonding pad 134, a fourth solder resist 135, and a through via 136.

The interposer substrate 131 may be made of an insulating material. The interposer substrate 131 may be formed to protect the first semiconductor device (140 of FIG. 1) mounted on the upper portion of the first package (110 of FIG. 1) from the second package (120 of FIG. 1). Therefore, the interposer substrate 131 may be formed to have a thickness thicker than the first semiconductor device (140 of FIG. 1).

The third bonding pad 132 may be formed below the interposer substrate 131. The third bonding pad 132 may be bonded to the first package (110 of FIG. 1) by the solder bump. That is, the third bonding pad 132 may be bonded to the first bonding pad 112 of the first package (110 of FIG. 1) by the solder bump. The third bonding pad 132 may be electrically connected to the first package (110 of FIG. 1). For example, a third bonding pad 132 of the interposer 130 may be electrically connected with the first bonding pad 112 of the first package (110 of FIG. 1). The third bonding pad 132 may be made of an electrical conductive material.

The third solder resist 133 may be formed below the interposer substrate 131. The third solder resist 133 is formed below the interposer substrate 131, but may be formed so as to expose the third bonding pad 132 to the outside.

The fourth bonding pad 134 may be formed above the interposer substrate 131. The fourth bonding pad 134 may be bonded to the second package (120 of FIG. 1) by the solder bump. That is, the fourth bonding pad 134 may be bonded to the second bonding pad 122 of the second package (120 of FIG. 1) by the solder bump. The fourth bonding pad 134 may be electrically connected to the second package (120 of FIG. 1). For example, the fourth bonding pad 134 of the interposer 130 may be electrically connected with the second bonding pad 122 of the second package (120 of FIG. 1). The fourth bonding pad 134 may be made of an electrical conductive material.

The fourth solder resist 135 may be formed above the interposer substrate 131. The fourth solder resist 135 is formed above the interposer substrate 131, but may be formed so as to expose the fourth bonding pad 134 to the outside.

The through via 136 may be formed to transmit electrical signals between the upper and lower portions of the interposer substrate 131. Therefore, the through via 136 may be formed to penetrate through the upper and lower portions of the interposer substrate 131. For example, a lower portion of the through via 136 may be formed so as to be electrically connected with the third bonding pad 132. In addition, an upper portion of the through via 136 may be formed so as to be electrically connected with the fourth bonding pad 134. The through via 136 may be made of an electrical conductive material.

As such, the first package (110 of FIG. 1) may be electrically connected with the second package (120 of FIG. 1) by the interposer 130 on which the through via 136 is formed.

According to the semiconductor package of the preferred embodiment of the present invention, the first package, the interposer, and the second package are directly connected with one another by the solder bump and as a result, it is possible to prevent a miss align between the interposer and the first package or the second package.

According to the semiconductor package of the preferred embodiment of the present invention, when the interposer is formed below the first package, an upper surface of a first solder resist of the first package may adhere to a lower surface of a third solder resist of the interposer by the first package, the second package, and the interposer. Further, when the second package is formed above the interposer, an upper surface of the fourth solder resist may adhere to a lower surface of the second solder resist of the second package. As such, the semiconductor package may be firmly formed by the structure in which the first package, the second package, and the interposer adhere with one another.

### Method of Manufacturing Semiconductor Package

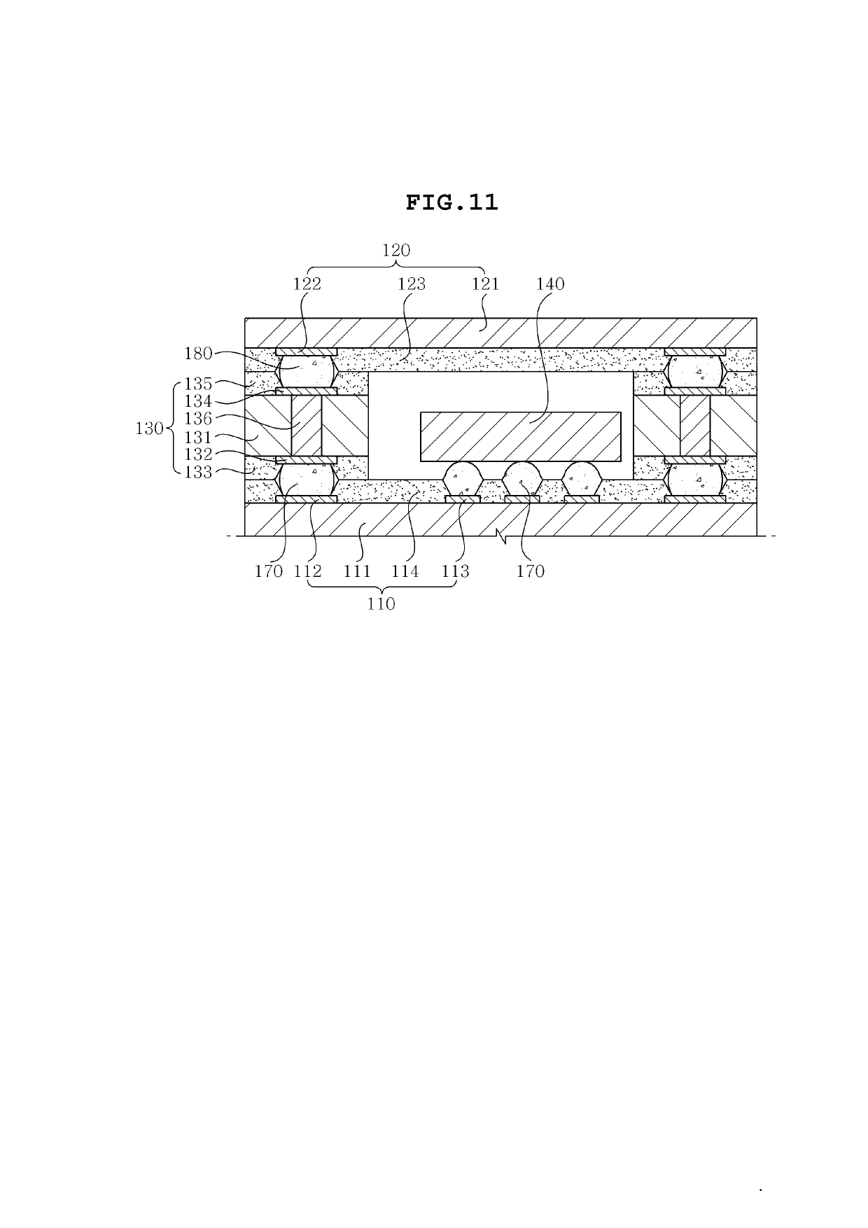

FIGS. 5 to 11 are diagrams illustrating a method of manufacturing a semiconductor package according to another preferred embodiment of the present invention.

For convenience of explanation, in FIGS. 5 to 10, a part of the semiconductor package will be described by way of example. However, the number of interposer, bonding pads, and device mounting pads formed on the semiconductor package and the formation location thereof are not limited thereto and therefore, may be easily changed in a design by those skilled in the art.

Referring to FIG. 5, the first package 100 may be prepared.

The first package 110 may include the first base substrate 111, the first bonding pad 112, the device mounting pad 113, and the first solder resist 114.

Although not illustrated in FIG. 5, the first base substrate 111 may be provided with an inner layer circuit of at least one layer. The upper portion of the first base substrate 111 may be provided with a plurality of first bonding pads 112, a plurality of device mounting pads 113, and a first solder resist 114.

The first bonding pad 112 formed above the first base substrate 111 is a component that is bonded to the interposer (130 of FIG. 7) by the solder bump. The first bonding pad 112 may be electrically connected with the interposer (130 of FIG. 7). Therefore, the first bonding pad 112 may be made of an electric conductive material.

The device mounting pad 113 is a component that is bonded to the first semiconductor device (not illustrated) mounted on the first package 110, by the solder bump. The device mounting pad 113 may be electrically connected with the first semiconductor device (not illustrated). Therefore, the device mounting pad 113 may be made of an electrical conductive material. In order to stably mount the first semiconductor device (not illustrated), the device mounting pad 113 may be formed in plural.

The first solder resist 114 may be formed above the first base substrate 111. The first solder resist 114 is formed above the first base substrate 111, but may be formed so as to expose the first bonding pad 112 and the device mounting pad 113 to the outside.

Referring to FIG. 6, the first package 110 may be applied with a first solder paste 171.

The first bonding pad 112 and the device mounting pad 113 on the upper portion of the first base substrate 111 may be applied with the first solder resist 171. The first solder paste 171 is made of a conductive material. The first solder paste 171 may be applied by a screen printing method. However, a method of applying the first solder paste is not limited to the screen printing method. That is, the first solder paste 171 may be applied by a general method of applying a solder paste.

Referring to FIG. 7, the interposer 130 may be formed above the first package 110.

The interposer 130 may include the interposer substrate 131, the third bonding pad 132, the third solder resist 133, the fourth bonding pad 134, the fourth solder resist 135, and the through via 136.

The interposer substrate 131 made of an insulating material may be formed to have a thickness thicker than the first semiconductor device 140 additionally mounted on the upper portion of the first package 110.

The third bonding pad 132 may be formed below the interposer substrate 131. The third bonding pad 132 may be made of an electrical conductive material.

The third solder resist 133 is formed above the interposer substrate 131, but may be formed so as to expose the third bonding pad 132 to the outside.

The fourth bonding pad 134 may be formed above the interposer substrate 131. The fourth bonding pad 134 may be made of an electrical conductive material.

The fourth solder resist 135 is formed above the interposer substrate 131, but may be formed so as to expose the fourth bonding pad 134 to the outside.

The through via 136 may be formed to penetrate through the upper and lower portions of the interposer substrate 131. For example, a lower portion of the through via 136 may be formed so as to be electrically connected with the third bonding pad 132. In addition, an upper portion of the through via 136 may be formed so as to be electrically connected with the fourth bonding pad 134. The through via 136 may be made of an electrical conductive material.

The upper portion of the first package 110 applied with the first solder paste 171 may be mounted with the interposer 130 having the structure according to the embodiment of the present invention. In this case, the interposer 130 may be formed so that the third bonding pad 132 is located on the upper portion of the first bonding pad 112 of the first package 110. Therefore, the third bonding pad 132 of the interposer 130 may contact the first solder paste 171 applied to the upper portion of the first bonding pad 112 of the first package 110.

Further, as the interposer 130 is mounted on the upper portion of the first package 110, the upper surface of the first solder resist 114 of the first package 110 may adhere to the lower surface of the third solder resist 133 of the interposer 130.

Referring to FIG. 8, a first reflow may be performed.

The first reflow may be performed in the state in which the interposer 130 is mounted on the upper portion of the first package 110. The first solder paste 171 applied to a space between the first bonding pad 112 of the first package 110 and the third bonding pad 132 of the interposer 130 by the first reflow may be the first solder bump 170. The first package 110 may be bonded to the interposer 130 by the first solder bump 170 formed as described above. In addition, the first solder bump 170 made of a conductive material may perform the electrical connection between the first package 110 and the interposer 130.

The first bonding pad 112 of the first package 110 is bonded to the third bonding pad 132 of the interposer 130 by the first solder bump and the upper surface of the first solder resist 114 of the first package adheres to the lower surface of the third solder resist 133 of the interposer 130, such that the first package 110 and the interposer 130 may be firmly stacked each other.

Further, as the first reflow is performed, both of the first solder paste 171 applied to the first bonding pad 112 of the first package 110 and the first solder paste 171 applied to the device mounting pad 113 may be the first solder bump 170. Further, the first semiconductor device (not illustrated) may be mounted on the upper portion of the first solder bump 170 that is formed above the device mounting pad 113.

Referring to FIG. 9, a second solder paste 181 may be applied to the upper portion of the interposer 130.

The second solder paste 181 may be applied to the upper portion of the fourth bonding pad 134 formed above the interposer 130. The second solder paste 181 is made of a conductive material. The second solder paste 181 may be applied by the screen printing method. However, the method of applying the second solder paste 181 is not limited to the screen printing method. That is, the second solder paste 181 may be applied by a general method of applying a solder paste.

Referring to FIG. 10, the second package 120 may be formed above the interposer 130.

The second package 120 is applied with the second solder paste 181 and may mount on the upper portion of the interposer 130 having the structure according to the preferred embodiment of the present invention. In this case, the second bonding pad 122 of the second package may be formed to be located on the upper portion of the fourth bonding pad 134. Therefore, the second bonding pad 122 of the second package 120 may contact the second solder paste 181 applied to the upper portion of the fourth bonding pad 134.

Further, as the second package 120 is mounted on the upper portion of the interposer 130, the upper surface of the fourth solder resist 135 of the interposer 130 may adhere to the lower surface of the second solder resist 123 of the second package 120.

Referring to FIG. 11, a second reflow may be performed.

The second reflow may be performed in the state in which the second package 120 is mounted on the upper portion of the interposer 130. The second solder paste (181 of FIG. 10) applied to a space between the fourth bonding pad 134 of the interposer 130 and the second bonding pad 122 of the second package 120 by the second first reflow may be the second solder bump 180. The second package 120 may be bonded to the interposer 130 by the second solder bump 180 formed as described above. In addition, the second solder bump 180 made of a conductive material may perform the electrical connection between the interposer 130 and the second package 120.

The fourth bonding pad 134 of the interposer 130 is bonded to the second bonding pad 122 of the second package 120 by the solder bump and the first solder resist 114 of the interposer 130 adheres to the lower surface of the third solder resist 133 of the second package 120, such that the interposer 130 and the second package 120 may be firmly stacked each other.

According to the method of manufacturing a semiconductor package of the preferred embodiment of the present invention, the bonding between the first package and the second package and the interposer is performed by the solder bump rather than by the solder ball and therefore, the reflow process may be reduced. That is, the process of forming the solder bump on the upper portion of the device mounting pad of the first package according to the prior art, the process of bonding the first bonding pad of the first package to the lower portion of the solder ball, and the process of bonding the upper portion of the solder ball to the interposer are each subjected to the reflow process. However, according to the preferred embodiment of the present invention, the solder paste is applied to the first bonding pad and the device mounting pad and both of the first bonding pad and the device mounting pad may be provided with the solder bump by mounting the interposer and then performing the reflow. Therefore, according to the method of manufacturing a package of the embodiment of the present invention, the reflow process frequency can be further reduced than the prior art. Further, it is possible to reduce the occurrence of the solder bump void by the reduction in the reflow process. Further, it is possible to reduce the possibility of product damage due to the reduction in the reflow process.

Further, according to the method of manufacturing a semiconductor package of the preferred embodiment of the present invention, the first package, the interposer, and the third package are directly connected with one another by the solder bump and as a result, it is possible to prevent a miss align between the interposer and the first package or the second package.

Further, according to the method of manufacturing a semiconductor package of the preferred embodiment of the present invention, the first package, the interposer, and the second package are bonded to one another by the solder bump at the time of stacking among the first package, the interposer, and the second package and the solder resists formed on the outer layers of each thereof adhere to one another to increase the bonding area, such that the first package, the interposer, and the second package can be firmly stacked one another.

Further, according to the semiconductor package and the method of manufacturing a semiconductor package of the preferred embodiment of the present invention, it is possible to reduce a thickness of the semiconductor package by removing the solder balls and directly bonding and stacking the package and the interposer.

Although the preferred embodiments of the present invention have been disclosed for illustrative purposes, they are for specifically explaining the present invention. Therefore, the preferred embodiments of the present invention is not limited thereto, but those skilled in the art will appreciate that various modifications and alteration are possible, without departing from the scope and spirit of the invention as disclosed in the accompanying claims.

Accordingly, such modifications and alterations should also be understood to fall within the scope of the present invention. A specific protective scope of the present invention could be defined by accompanying claims.

What is claimed is:

1. A semiconductor package, comprising:
a first package having a first semiconductor element mounted on an upper portion thereof and at least one solder ball formed on a lower portion thereof;
a second package stacked on the upper portion of the first package; and
an interposer formed between the first package and the second package and formed so that a lower portion of the interposer adheres to the upper portion of the first package and an upper portion thereof adheres to a lower portion of the second package.

2. The semiconductor package as set forth in claim 1, wherein the interposer electrically connects the first package and the second package.

3. The semiconductor package as set forth in claim 1, wherein the interposer includes:
an interposer substrate made of an insulating material;
a third bonding pad formed below the interposer substrate and bonded to the first package by a solder bump;
a third solder resist formed below the interposer substrate and formed to expose the third bonding pad;
a fourth bonding pad formed above the interposer substrate and bonded to the second package by the solder bump;
a fourth solder resist formed above the interposer substrate and formed to expose the fourth bonding pad; and
a through via formed to penetrate through the interposer substrate and electrically connecting the third bonding pad and the fourth bonding pad.

4. The semiconductor package as set forth in claim 3, wherein the first package includes:
a first base substrate;
a first bonding pad formed above the first base substrate and bonded to the interposer by the solder bump; and
a first solder resist formed above the first base substrate and formed to expose the first bonding pad.

5. The semiconductor package as set forth in claim 4, wherein an upper portion of the first solder resist of the first package and a lower portion of a third solder resist of the interposer are bonded to each other.

6. The semiconductor package as set forth in claim 4, wherein the first package further includes a device mounting pad formed above the first base substrate and mounted with the first semiconductor device.

7. The semiconductor package as set forth in claim 3, wherein the second package includes:
a second base substrate;
a second bonding pad formed below the second base substrate and bonded to the interposer by the solder bump; and
a second solder resist formed below the second base substrate and formed to expose the second bonding pad.

8. The semiconductor package as set forth in claim 7, wherein a lower portion of a second solder resist of the second package and an upper portion of a fourth solder resist of the interposer are bonded to each other.

9. The semiconductor package as set forth in claim 7, further comprising:
a second semiconductor device mounted on the second base substrate.

10. A method of manufacturing a semiconductor package, comprising:
preparing a first package;
applying a first solder paste to an upper portion of the first package;
stacking an interposer to the upper portion of the first package to which the first solder paste is applied;
performing a first reflow;
applying a second solder paste to the upper portion of the interposer;
stacking the second package on the upper portion of the interposer to which the second solder paste is applied; and
performing a second reflow.

11. The method as set forth in claim 10, wherein in the applying of the first solder paste, a first solder paste is formed above the first package and is applied to an upper portion of a first bonding pad exposed to the outside by a first solder resist formed above the first package.

12. The method as set forth in claim 10, wherein in the stacking of the interposer on the upper portion of the first package, an upper portion of the first solder resist formed above the first package and a lower portion of a third solder resist formed below the interposer are bonded to each other.

13. The method as set forth in claim 10, wherein in the performing of the first reflow, the first solder paste is formed as a first solder bump by the first reflow.

14. The method as set forth in claim 10, wherein in the applying of the second solder paste, a second solder paste is formed above the interposer and is applied to an upper portion of a fourth bonding pad exposed to the outside by a fourth solder resist formed above the interposer.

15. The method as set forth in claim 10, wherein in the stacking of the second package on the upper portion of the interposer, an upper portion of a fourth solder resist formed above the interposer and a lower portion of a second solder resist formed below the second package are bonded to each other.

16. The method as set forth in claim 10, wherein in the performing of the second reflow, the second solder paste is formed as a second solder bump by a second reflow.

17. The method as set forth in claim 10, wherein in the applying of the first solder paste, the first solder paste is formed above the first package and is applied to an upper portion of a mounting pad on which a first semiconductor device is mounted.

18. The semiconductor package as set forth in claim 17, further comprising:
after the applying of the first solder paste,
mounting the first semiconductor device on an upper portion of the mounting pad of the first package.

19. The semiconductor package as set forth in claim 10, further comprising:
after the stacking of the second package,
mounting a second semiconductor device on an upper portion of the second package.
